(19) United States
(12) Patent Application Publication
(10) Pub. No.: US 2025/0279148 A1
(43) Pub. Date: Sep. 4, 2025

(54) RECONFIGURABLE TESTING OF AN INTEGRATED CIRCUIT

(71) Applicant: INTERNATIONAL BUSINESS MACHINES CORPORATION, ARMONK, NY (US)

(72) Inventors: UMA SRINIVASAN, POUGHKEEPSIE, NY (US); DANIEL RODKO, POUGHKEEPSIE, NY (US); MATTHEW STEVEN HYDE, WAPPINGERS FALLS, NY (US); THOMAS J. KNIPS, WAPPINGERS FALLS, NY (US)

(21) Appl. No.: 18/592,840

(22) Filed: Mar. 1, 2024

(51) Int. Cl. G11C 29/14

(52) U.S. Cl. CPC G11C 29/14

(57) ABSTRACT

Reconfigurable testing of an integrated circuit includes storing, in a register, one or more values indicating at least a partial order in which a plurality of built-in self-test (BIST) engines are to respectively test a corresponding plurality of sets of memory arrays. A logic circuit coupled to the register causes the plurality of BIST engines to test the plurality of sets of memory arrays based on the one or more values stored in the register.

### BACKGROUND

The present disclosure relates to methods, apparatus, and products for reconfigurable testing of an integrated circuit.

### SUMMARY

According to embodiments of the present disclosure, various methods, apparatus and products for reconfigurable testing of an integrated circuit are described herein. In some aspects, reconfigurable testing of an integrated circuit includes storing, in a register, one or more values indicating at least a partial order in which a plurality of built-in self-test (BIST) engines are to respectively test a corresponding plurality of sets of memory arrays. A logic circuit coupled to the register causes the plurality of BIST engines to test the plurality of sets of memory arrays based on the one or more values stored in the register.

### BRIEF DESCRIPTION OF THE DRAWINGS

FIG. 1 sets forth a block diagram of an integrated circuit with reconfigurable built-in self-test (BIST) circuitry according to aspects of the present disclosure.

FIG. 2 sets forth a diagram of reconfigurable BIST circuitry according to aspects of the present disclosure.

FIG. 3 sets forth a diagram of reconfigurable BIST circuitry according to further aspects of the present disclosure.

FIG. 4 sets forth a diagram of logic circuitry for reconfiguring BIST testing according to aspects of the present disclosure.

FIG. 5 sets forth a diagram of logic circuitry for reconfiguring BIST testing according to further aspects of the present disclosure.

FIG. 6 sets forth a flowchart of an example method for reconfigurable testing of an integrated circuit according to aspects of the present disclosure.

### DETAILED DESCRIPTION

Modern-day digital signal processors, microprocessors, and network chips process lots of information and store the processed data into memory. Memory typically occupies almost half of the chip area. With decreasing technology nodes, more and more memory cells are closely packed together, thereby increasing the frequency and number of memory faults being detected.

A built-in self-test (BIST) mechanism within an integrated circuit (IC) is a function that verifies all or a portion of the internal functionality of the IC. There are many different approaches to architecting memory BIST, each of which has distinct advantages and disadvantages. With advances in technologies and device scaling, integrated circuit chip designs incorporate an increasingly large number of embedded memories (also referred to herein as embedded memory arrays) as well as BIST circuits for testing such embedded memories, when operating in a test mode (as opposed to a functional mode). A BIST engine may be configured to test the memory arrays for defects and faults. For example, a cell or group of cells located within the array may be unable to properly read or write data. The BIST engine may test for functional errors specific to the memory array. As an example, the memory array read and memory array write functionality may be tested according to a read-write vector. A data vector may be written to a group of memory addresses defined by a memory address vector, and the read-write vector may determine which of the particular memory addresses are read or written.

An integrated circuit chip design may incorporate multiple BIST engines controlled by a BIST controller, and each BIST engine may test multiple embedded memories of the same specific type (e.g., multiple static random access memory arrays (SRAMs), multiple dynamic random access memory arrays (DRAMs), etc.) in parallel. It should be noted that although embodiments of the present disclosure are described herein using examples of electric circuits that serve as memory block(s), in other embodiments of the present disclosure the features can be used in any repairable circuit, including but not limited to input/output, logic, SRAM, and DRAM.

An example of the present disclosure is directed to a method for reconfigurable testing of an integrated circuit, which includes storing, in a register, one or more values indicating at least a partial order in which a plurality of built-in self-test (BIST) engines are to respectively test a corresponding plurality of sets of memory arrays. The method includes causing, by a logic circuit coupled to the register, the plurality of BIST engines to test the plurality of sets of memory arrays based on the one or more values stored in the register.

In an example of the method, the one or more values stored in the register are determined based on tests in hardware or simulation. In an example of the method, the one or more values stored in the register indicate an ordering of the plurality of BIST engines that balances power across a total period of testing.

In an example of the method, the logic circuit selects a first one of the BIST engines to run before other ones of the BIST engines based on the one or more values stored in the register, and the other ones of the BIST engines run in a predetermined sequence following the running of the first one of the BIST engines. In an example of the method, the first one of the BIST engines sends a signal to a second one of the BIST engines upon completion of testing by the first one of the BIST engines to cause the second one of the BIST engines to begin testing.

In an example of the method, the one or more values stored in the register indicate a complete order in which the plurality of BIST engines are to sequentially test the plurality of sets of memory arrays. In an example of the method, the logic circuit includes a multiplexer coupled to the register to selectively output one of a plurality of possible orders of the BIST engines based on the one or more values stored in the register.

An example of the method also includes causing, by the logic circuit, a first subset of the BIST engines to run in parallel and a second subset of the BIST engines to run in a serial manner.

Another example of the present disclosure is directed to a system, which includes a plurality of sets of memory arrays. The system includes a plurality of built-in self-test (BIST) engines. The system includes a register to store one or more values indicating at least a partial order in which the plurality of BIST engines are to respectively test the plurality of sets of memory arrays. The system includes a logic circuit coupled to the register to cause the plurality of BIST engines to test the plurality of sets of memory arrays based on the one or more values stored in the register.

In an example of the system, the one or more values stored in the register are determined based on tests in hardware or simulation. In an example of the system, the one or more values stored in the register indicate an ordering of the plurality of BIST engines that balances power across a total period of testing.

In an example of the system, the logic circuit selects a first one of the BIST engines to run before other ones of the BIST engines based on the one or more values stored in the register, and the other ones of the BIST engines run in a predetermined sequence following the running of the first one of the BIST engines. In an example of the system, the first one of the BIST engines sends a signal to a second one of the BIST engines upon completion of testing by the first one of the BIST engines to cause the second one of the BIST engines to begin testing.

In an example of the system, the one or more values stored in the register indicate a complete order in which the plurality of BIST engines are to sequentially test the plurality of sets of memory arrays. In an example of the system, the logic circuit includes a multiplexer coupled to the register to selectively output one of a plurality of possible orders of the BIST engines based on the one or more values stored in the register.

In an example of the system, the logic circuit causes a first subset of the BIST engines to run in parallel and a second subset of the BIST engines to run in a serial manner.

Another example of the present disclosure is directed to an apparatus for reconfigurable testing of an integrated circuit, which includes a plurality of built-in self-test (BIST) engines. The apparatus includes a register to store one or more values indicating at least a partial order in which the plurality of BIST engines are to respectively test a corresponding plurality of sets of memory arrays. The apparatus includes a logic circuit coupled to the register to cause the plurality of BIST engines to test the plurality of sets of memory arrays based on the one or more values stored in the register.

In an example of the apparatus, the logic circuit selects a first one of the BIST engines to run before other ones of the BIST engines based on the one or more values stored in the register, and the other ones of the BIST engines run in a predetermined sequence following the running of the first one of the BIST engines. In an example of the apparatus, the one or more values stored in the register indicate a complete order in which the plurality of BIST engines are to sequentially test the plurality of sets of memory arrays. In an example of the apparatus, the logic circuit causes a first subset of the BIST engines to run in parallel and a second subset of the BIST engines to run in a serial manner.

A technical challenge with BIST is that driving multiple memory array groups from BIST engines in parallel may result in a high power cost. Starting multiple BIST engines at the same time may cause a power spike. Such testing may not match the functional behavior of the integrated circuit chip.

Examples of the present disclosure facilitate technical solutions that address the above described technical challenges without the drawbacks of existing solutions. Some examples disclosed herein provide a reconfigurable BIST engine mode to test memory array groups sequentially in a specified order, wherein completion of one BIST engine causes the next BIST engine in the series to begin. By providing flexibility and control over the order in which BIST engines are run, the order may be selected to avoid or reduce power spikes and a high power cost, and the testing may more closely match the functional behavior of the integrated circuit chip. For example, if the system includes noise before the start of BIST, the BIST engine sequence can be reordered to cause the higher-power BIST engines to start after the noise event ends to reduce the peak power. Some examples provide for the reconfigurability of the BIST engine sequence post hardware to optimize power and reduce redesign costs. Examples of the present disclosure improve the self-testing of integrated circuit chips and provide an improvement to computing technology. Examples of the present disclosure accordingly provide a practical application to the technical challenges described herein in the field of computing technology and particularly electrical circuits used in computing devices, such as memory devices.

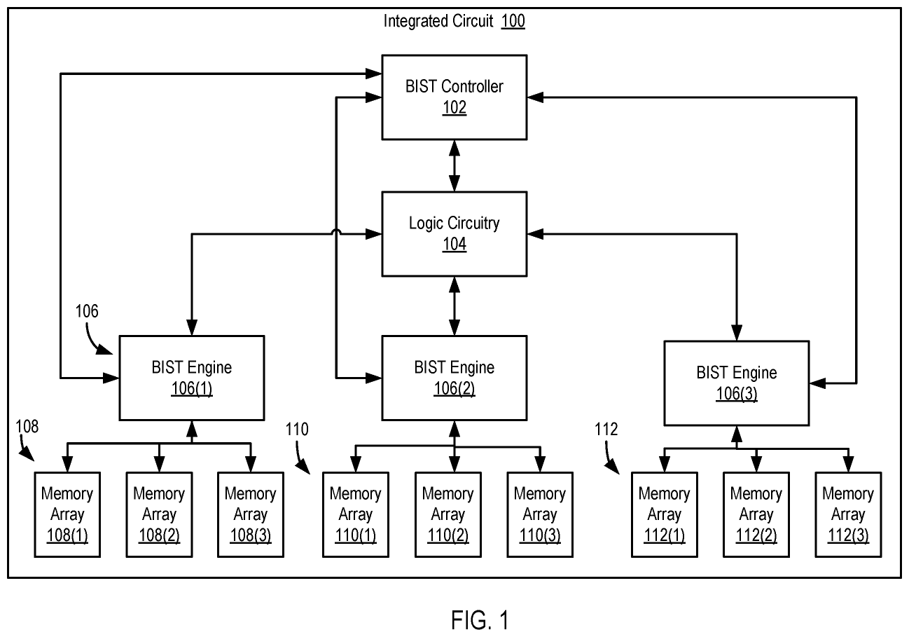

FIG. 1 sets forth a block diagram of an integrated circuit 100 with reconfigurable BIST circuitry according to aspects of the present disclosure. Integrated circuit 100 includes BIST controller 102, logic circuitry 104, BIST engines 106(1)-106(3) (collectively referred to as BIST engines 106), memory arrays 108(1)-108(3) (collectively referred to as memory arrays 108), memory arrays 110(1)-110(3) (collectively referred to as memory arrays 110), and memory arrays 112(1)-112(3) (collectively referred to as memory arrays 112). In some examples, BIST engines 106(1)-106(3) perform testing on memory arrays 108, 110, and 112, respectively.

In some examples, the integrated circuit 100, which may also be referred to in some implementations as an integrated circuit chip, may include, central processing units (CPUs), digital signal processing (DSP) chips, graphical processing units (GPUs), system-on-a-chip (SOC), three-dimensional integrated circuits (3D-IC), application-specific integrated circuits (ASICs), and various memory such as volatile memory, random access memory (RAM), nonvolatile random access memory (NVRAM), read-only memory (ROM), programmable read-only memory (PROM), erasable programmable read-only memory (EPROM), and solid-state drive (SSD).

For purposes of illustration, FIG. 1 shows the integrated circuit 100 having nine discrete memory arrays 108(1)-108(3), 110(1)-110(3), and 112(1)-112(3). However, in other examples, the integrated circuit 100 may include any number of two or more memory arrays. In the illustrated example, integrated circuit 100 includes three BIST engines 106(1)-106(3) controlled by BIST controller 102 and logic circuitry 104. In other examples, integrated circuit 100 may include any number of two or more BIST engines 106 controlled by the BIST controller 102 and logic circuitry 104.

BIST engine 106(1) is electrically connected to memory arrays 108(1)-108(3) and may be configured to concurrently test those memory arrays in parallel. BIST engine 106(2) is electrically connected to memory arrays 110(1)-110(3) and may be configured to concurrently test those memory arrays in parallel. BIST engine 106(3) is electrically connected to memory arrays 112(1)-112(3) and may be configured to concurrently test those memory arrays in parallel. For illustration purposes, the three BIST engines 106 are shown in FIG. 1 as each being electrically connected to three memory arrays. However, in other examples, each of the BIST engines 106 may be electrically connected to any number of memory arrays.

The memory arrays 108, 110, and 112 may be the same type of memory arrays or may include different types of memory arrays. The memory arrays 108, 110, and 112 may all be DRAM arrays, SRAM arrays, or any other specific type of memory arrays, or may include combinations of these different types of memory arrays. Each of the memory arrays may be associated with a predetermined maximum address space. For example, an SRAM array may have a maximum possible size of 16 banks, 512-word lines per bank and a decode number of 32 (i.e., a decode 32) and, thereby a maximum possible address space of 256K addresses (where 1K=2¹⁰=1024). Any other values/limits may be used in other examples.

In some examples, the memory arrays 108, 110, and 112 may have the same configuration (e.g., the same number of banks, the same number of word lines per bank and the same decode number per data bit column) such that they each have the same total address space. In other examples, any two or more of the memory arrays may have different configurations (e.g., different numbers of banks, different numbers of word lines per bank and/or different decode numbers per data bit column) such that they have different total address spaces.

In some examples, each of the BIST engines 106 includes an address generator that, during testing, generates test addresses sufficient to automatically sweep through a predetermined maximum address space (e.g., 256K addresses) of the specific type of memory under test. In some examples, the address generator may be limited to generate test addresses within a predetermined range to test particular portions of the memory arrays. The integrated circuit 100 may further include failing address registers (FARs) in communication with the BIST engines 106.

In some examples, the BIST engines 106 sweep through the address spaces of each memory array connected to the BIST engine 106, and write test patterns to the memory cells in the memory arrays at the test addresses generated by the test address generator of the BIST engine 106. The BIST engines 106 may subsequently cause the memory cells at the test addresses in the memory arrays to be read and analyzed by comparison logic in order to detect any faulty memory cells in any of the memory arrays 108, 110, and 112. Upon detection of faulty memory cells in any of the memory arrays 108, 110, and 112, the corresponding FARs register the failing addresses and can calculate appropriate repair solutions.

Computer readable program instructions may be loaded onto integrated circuit 100 to cause a series of operational steps to be performed by a processor and thereby effect a computer-implemented method, such that the instructions thus executed will instantiate the methods specified in flowcharts and/or narrative descriptions of computer-implemented methods included in this document. These computer readable program instructions are stored in various types of computer readable storage media. The program instructions, and associated data, are accessed by the processor to control and direct performance of the computer-implemented methods.

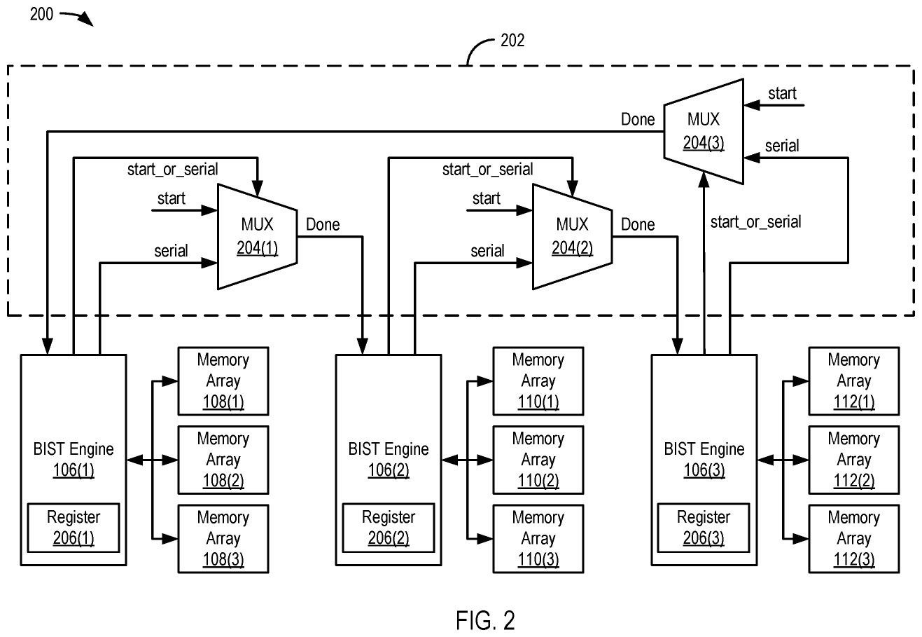

FIG. 2 sets forth a diagram of reconfigurable BIST circuitry 200 according to aspects of the present disclosure. Reconfigurable BIST circuitry 200 includes logic circuitry 202 and BIST engines 106(1)-106(3). Logic circuitry 202 is an example implementation of logic circuitry 104 (FIG. 1). Logic circuitry 202 includes multiplexers (MUXs) 204(1)-204(3). Multiplexers 204(1)-204(3) each receive a start input signal and a serial input signal and output a DONE output signal in response to a received start_or_serial control signal. Logic circuitry 202 allows partial reconfiguration of the BIST testing in that any one of the BIST engines 106 may be selected as the starting BIST engine, and the remaining BIST engines operate in a serial mode. Thus, the BIST engines 106 are in a circular DONE loop. The starting BIST engine may be selected, for example, based on DI/DT (i.e., the change in current over the change in time) requirements.

As an example, if BIST engine 106(1) is selected as the starting BIST engine, BIST engine 106(1) will be followed by BIST engine 106(2), which will be followed by BIST engine 106(3). As another example, if BIST engine 106(2) is selected as the starting BIST engine, BIST engine 106(2) will be followed by BIST engine 106(3), which will be followed by BIST engine 106(1). As another example, if BIST engine 106(3) is selected as the starting BIST engine, BIST engine 106(3) will be followed by BIST engine 106(1), which will be followed by BIST engine 106(2). A register or latch to control start or serial may be located inside or outside the BIST engines 106. In the illustrated example, the BIST engines 106(1)-106(3) include registers 206(1)-206(3), respectively, to control start or serial.

If BIST engine 106(2), for example, is selected as the starting BIST engine, the start input signal may be set high and the serial input signal may be set low for the BIST engine 106(2). For the remaining BIST engines 106(3) and 106(1), the start input signal may be set low and the serial input signal may be set high. When BIST engine 106(2) completes its testing, it may send a start_or_serial signal that selects the start input signal so that the DONE output signal is output from MUX 204(2). BIST engine 106(3) receives the DONE output signal from MUX 204(2) and, in response, begins its testing. When BIST engine 106(3) completes its testing, it may send a start_or_serial signal that selects the serial input signal so that the DONE output signal is output from MUX 204(3). BIST engine 106(1) receives the DONE output signal from MUX 204(3) and, in response, begins its testing.

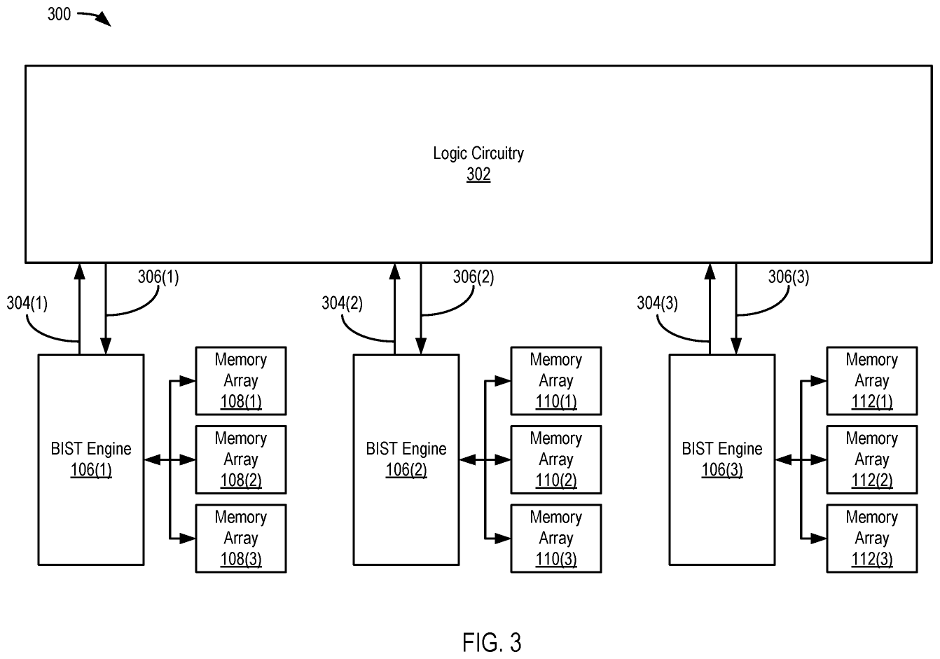

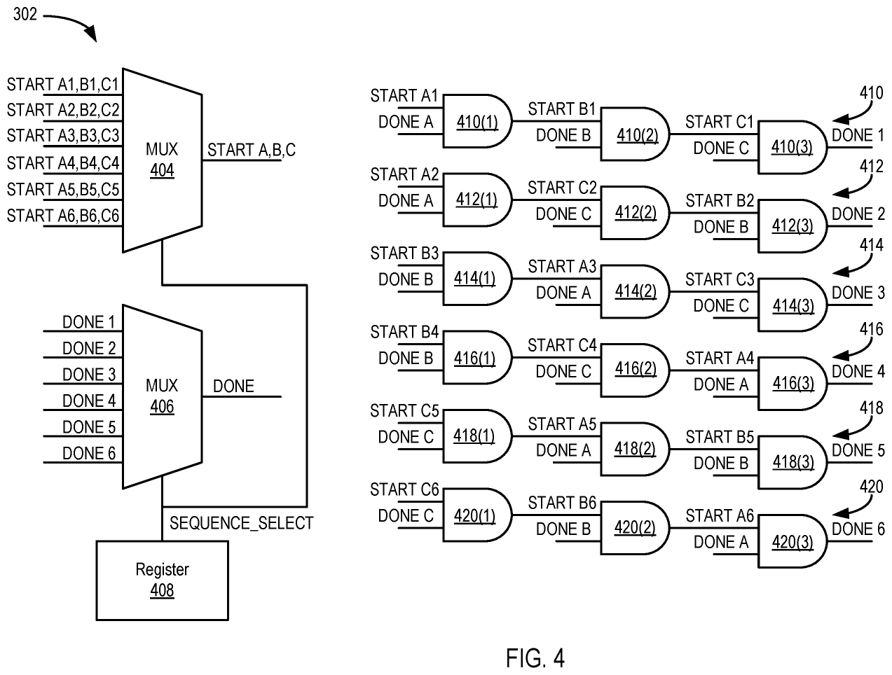

FIG. 3 sets forth a diagram of reconfigurable BIST circuitry 300 according to further aspects of the present disclosure. Reconfigurable BIST circuitry 300 includes logic circuitry 302 and BIST engines 106(1)-106(3). Logic circuitry 302 is an example implementation of logic circuitry 104 (FIG. 1) and is shown in more detail in FIG. 4. Logic circuitry 302 allows full reconfiguration of the BIST testing in that any one of the BIST engines 106 may be selected as the starting BIST engine, and the order of the remaining BIST engines 106 may also be selected. The BIST engines 106 are in a fully reconfigurable DONE daisy chain to change BIST engine order. The order of the BIST engines 106 may be determined, for example, by empirically determining DI/DT for each of the sets of memory arrays 108, 110, and 112, and putting testing of the memory arrays with lower DI/DT before testing of the memory arrays with higher DI/DT to reduce DI/DT at the start of testing.

The logic circuitry 302 sends start signals to the BIST engines 106(1)-106(3) via communication links 306(1)-306(3), respectively, to cause the respective BIST engine to begin testing. The logic circuitry 302 receives DONE signals from the BIST engines 106(1)-106(3) via communication links 304(1)-304(3), respectively, to indicate to the logic circuitry 302 that the respective BIST engine has completed its testing.

FIG. 4 sets forth a diagram of logic circuitry 302 for reconfiguring BIST testing according to aspects of the present disclosure. Logic circuitry 302 includes multiplexers (MUXs) 404 and 406, register 408, and six sets of three connected AND gates 410(1)-410(3), 412(1)-412(3), 414(1)-414(3), 416(1)-416(3), 418(1)-418(3), and 420(1)-420(3). AND gates 410(1)-410(3) may collectively be referred to as AND gates 410. AND gates 412(1)-412(3) may collectively be referred to as AND gates 412. AND gates 414(1)-414(3) may collectively be referred to as AND gates 414. AND gates 416(1)-416(3) may collectively be referred to as AND gates 416. AND gates 418(1)-418(3) may collectively be referred to as AND gates 418. AND gates 420(1)-420(3) may collectively be referred to as AND gates 420.

Multiplexer 404 includes six START inputs respectively corresponding to six different sequences of the BIST engines 106(1)-106(3). The first input of multiplexer 404 corresponds to a START A1,B1,C1 sequence, which indicates that start signals are sent in sequence to the BIST engines in the following order: BIST engine 106(1), BIST engine 106(2), and BIST engine 106(3). The second input of multiplexer 404 corresponds to a START A2,B2,C2 sequence, which indicates that start signals are sent in sequence to the BIST engines in the following order: BIST engine 106(1), BIST engine 106(3), and BIST engine 106(2). The third input of multiplexer 404 corresponds to a START A3,B3,C3 sequence, which indicates that start signals are sent in sequence to the BIST engines in the following order: BIST engine 106(2), BIST engine 106(1), and BIST engine 106(3). The fourth input of multiplexer 404 corresponds to a START A4,B4,C4 sequence, which indicates that start signals are sent in sequence to the BIST engines in the following order: BIST engine 106(2), BIST engine 106(3), and BIST engine 106(1). The fifth input of multiplexer 404 corresponds to a START A5,B5,C5 sequence, which indicates that start signals are sent in sequence to the BIST engines in the following order: BIST engine 106(3), BIST engine 106(1), and BIST engine 106(2). The sixth input of multiplexer 404 corresponds to a START A6,B6,C6 sequence, which indicates that start signals are sent in sequence to the BIST engines in the following order: BIST engine 106(3), BIST engine 106(2), and BIST engine 106(1).

Multiplexer 406 includes six DONE inputs (DONE 1-DONE 6) that respectively correspond to the six START inputs of multiplexer 404. Register 408 stores a SEQUENCE_SELECT value representing an order in which the BIST engines 106(1)-106(3) are to perform their testing. In some examples, SEQUENCE_SELECT is one of six possible values that respectively correspond to the six inputs of multiplexer 404 and the six inputs of multiplexer 406. Register 408 outputs the SEQUENCE_SELECT value to multiplexers 404 and 406 to cause multiplexers 404 and 406 to output the selected input.

The six sequences corresponding to the six inputs of the multiplexer 404 respectively correspond to the six sets of AND gates 410, 412, 414, 416, 418, and 420. Thus, for example, if the first inputs of the multiplexers 404 and 406 are selected based on the SEQUENCE_SELECT value in the register 408, then AND gates 410(1)-410(3) control the starting of the BIST engines 106(1)-106(3). In particular, BIST engine 106(1) is started first with the START A1 signal, which is also provided as an input to the AND gate 410(1). When the BIST engine 106(1) completes its testing, it provides a DONE A signal to the AND gate 410(1). At this point, both inputs of the AND gate 410(1) will be a logical “1”, which will cause the AND gate 410(1) to output a START B1 signal to an input of AND gate 410(2), and to cause BIST engine 106(2) to start performing its testing. When the BIST engine 106(2) completes its testing, it provides a DONE B signal to the AND gate 410(2). At this point, both inputs of the AND gate 410(2) will be a logical “1”, which will cause the AND gate 410(2) to output a START C1 signal to an input of AND gate 410(3), and to cause BIST engine 106(3) to start performing its testing. When the BIST engine 106(3) completes its testing, it provides a DONE C signal to the AND gate 410(3). At this point, both inputs of the AND gate 410(3) will be a logical “1”, which will cause the AND gate 410(3) to output a DONE 1 signal to the first input of the multiplexer 406. Since the first input of the multiplexer 406 is selected based on the sequence value in the register 408, the multiplexer 406 will output the selected DONE 1 signal, indicating that the sequence of BIST engines has completed their testing.

If the second inputs of the multiplexers 404 and 406 are selected based on the SEQUENCE_SELECT value in the register 408, then AND gates 412(1)-412(3) control the starting of the BIST engines 106(1)-106(3). In particular, BIST engine 106(1) is started first with the START A2 signal, which is also provided as an input to the AND gate 412(1). When the BIST engine 106(1) completes its testing, it provides a DONE A signal to the AND gate 412(1). At this point, both inputs of the AND gate 412(1) will be a logical “1”, which will cause the AND gate 412(1) to output a START C2 signal to an input of AND gate 412(2), and to cause BIST engine 106(3) to start performing its testing. When the BIST engine 106(3) completes its testing, it provides a DONE C signal to the AND gate 412(2). At this point, both inputs of the AND gate 412(2) will be a logical “1”, which will cause the AND gate 412(2) to output a START B2 signal to an input of AND gate 412(3), and to cause BIST engine 106(2) to start performing its testing. When the BIST engine 106(2) completes its testing, it provides a DONE B signal to the AND gate 412(3). At this point, both inputs of the AND gate 412(3) will be a logical “1”, which will cause the AND gate 412(3) to output a DONE 2 signal to the second input of the multiplexer 406. Since the second input of the multiplexer 406 is selected based on the sequence value in the register 408, the multiplexer 406 will output the selected DONE 2 signal, indicating that the sequence of BIST engines has completed their testing.

If the third inputs of the multiplexers 404 and 406 are selected based on the SEQUENCE_SELECT value in the register 408, then AND gates 414(1)-414(3) control the starting of the BIST engines 106(1)-106(3). In particular, BIST engine 106(2) is started first with the START B3 signal, which is also provided as an input to the AND gate 414(1). When the BIST engine 106(2) completes its testing, it provides a DONE B signal to the AND gate 414(1). At this point, both inputs of the AND gate 414(1) will be a logical “1”, which will cause the AND gate 414(1) to output a START A3 signal to an input of AND gate 414(2), and to cause BIST engine 106(1) to start performing its testing. When the BIST engine 106(1) completes its testing, it provides a DONE A signal to the AND gate 414(2). At this point, both inputs of the AND gate 414(2) will be a logical “1”, which will cause the AND gate 414(2) to output a START C3 signal to an input of AND gate 414(3), and to cause BIST engine 106(3) to start performing its testing. When the BIST engine 106(3) completes its testing, it provides a DONE C signal to the AND gate 414(3). At this point, both inputs of the AND gate 414(3) will be a logical “1”, which will cause the AND gate 414(3) to output a DONE 3 signal to the third input of the multiplexer 406. Since the third input of the multiplexer 406 is selected based on the sequence value in the register 408, the multiplexer 406 will output the selected DONE 3 signal, indicating that the sequence of BIST engines has completed their testing.

If the fourth inputs of the multiplexers 404 and 406 are selected based on the SEQUENCE_SELECT value in the register 408, then AND gates 416(1)-416(3) control the starting of the BIST engines 106(1)-106(3). In particular, BIST engine 106(2) is started first with the START B4 signal, which is also provided as an input to the AND gate 416(1). When the BIST engine 106(2) completes its testing, it provides a DONE B signal to the AND gate 416(1). At this point, both inputs of the AND gate 416(1) will be a logical “1”, which will cause the AND gate 416(1) to output a START C4 signal to an input of AND gate 416(2), and to cause BIST engine 106(3) to start performing its testing. When the BIST engine 106(3) completes its testing, it provides a DONE C signal to the AND gate 416(2). At this point, both inputs of the AND gate 416(2) will be a logical “1”, which will cause the AND gate 416(2) to output a START A4 signal to an input of AND gate 416(3), and to cause BIST engine 106(1) to start performing its testing. When the BIST engine 106(1) completes its testing, it provides a DONE A signal to the AND gate 416(3). At this point, both inputs of the AND gate 416(3) will be a logical “1”, which will cause the AND gate 416(3) to output a DONE 4 signal to the fourth input of the multiplexer 406. Since the fourth input of the multiplexer 406 is selected based on the sequence value in the register 408, the multiplexer 406 will output the selected DONE 4 signal, indicating that the sequence of BIST engines has completed their testing.

If the fifth inputs of the multiplexers 404 and 406 are selected based on the SEQUENCE_SELECT value in the register 408, then AND gates 418(1)-418(3) control the starting of the BIST engines 106(1)-106(3). In particular, BIST engine 106(3) is started first with the START C5 signal, which is also provided as an input to the AND gate 418(1). When the BIST engine 106(3) completes its testing, it provides a DONE C signal to the AND gate 418(1). At this point, both inputs of the AND gate 418(1) will be a logical “1”, which will cause the AND gate 418(1) to output a START A5 signal to an input of AND gate 418(2), and to cause BIST engine 106(1) to start performing its testing. When the BIST engine 106(1) completes its testing, it provides a DONE A signal to the AND gate 418(2). At this point, both inputs of the AND gate 418(2) will be a logical “1”, which will cause the AND gate 418(2) to output a START B5 signal to an input of AND gate 418(3), and to cause BIST engine 106(2) to start performing its testing. When the BIST engine 106(2) completes its testing, it provides a DONE B signal to the AND gate 418(3). At this point, both inputs of the AND gate 418(3) will be a logical “1”, which will cause the AND gate 418(3) to output a DONE 5 signal to the fifth input of the multiplexer 406. Since the fifth input of the multiplexer 406 is selected based on the sequence value in the register 408, the multiplexer 406 will output the selected DONE 5 signal, indicating that the sequence of BIST engines has completed their testing.

If the sixth inputs of the multiplexers 404 and 406 are selected based on the SEQUENCE_SELECT value in the register 408, then AND gates 420(1)-420(3) control the starting of the BIST engines 106(1)-106(3). In particular, BIST engine 106(3) is started first with the START C6 signal, which is also provided as an input to the AND gate 420(1). When the BIST engine 106(3) completes its testing, it provides a DONE C signal to the AND gate 420(1). At this point, both inputs of the AND gate 420(1) will be a logical “1”, which will cause the AND gate 420(1) to output a START B6 signal to an input of AND gate 420(2), and to cause BIST engine 106(2) to start performing its testing. When the BIST engine 106(2) completes its testing, it provides a DONE B signal to the AND gate 420(2). At this point, both inputs of the AND gate 420(2) will be a logical “1”, which will cause the AND gate 420(2) to output a START A6 signal to an input of AND gate 420(3), and to cause BIST engine 106(1) to start performing its testing. When the BIST engine 106(1) completes its testing, it provides a DONE A signal to the AND gate 420(3). At this point, both inputs of the AND gate 420(3) will be a logical “1”, which will cause the AND gate 420(3) to output a DONE 6 signal to the sixth input of the multiplexer 406. Since the sixth input of the multiplexer 406 is selected based on the sequence value in the register 408, the multiplexer 406 will output the selected DONE 6 signal, indicating that the sequence of BIST engines has completed their testing.

The configuration of the logic circuitry 302 may vary based on the number, N, of BIST engines 106. There are N! possible orderings of the BIST engines 106. In the illustrated example, N=3, resulting in six possible orderings of the BIST engines 106(1)-106(3). In some examples, logic circuitry 302 provides a START/DONE sequence for each of the N! possible ordering of the BIST engines 106, including N! multiplexer decodes, and a register 408 for all decode combinations. In other examples, logic circuitry 302 may cover less than all possible orderings of the BIST engines 106. For example, an expert derived subset of the possible orderings may be implemented.

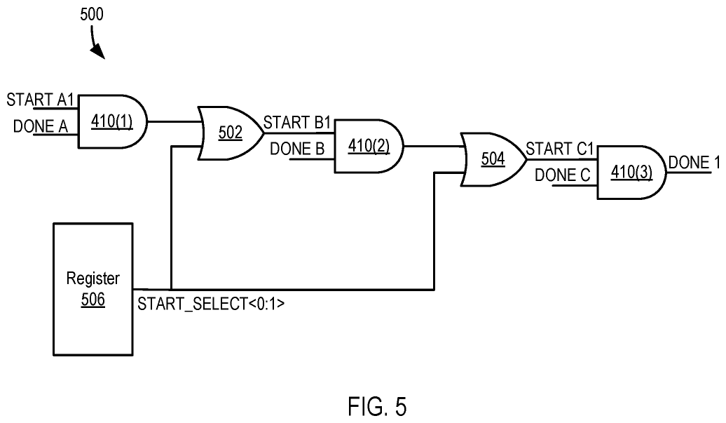

FIG. 5 sets forth a diagram of logic circuitry 500 for reconfiguring BIST testing according to further aspects of the present disclosure. Logic circuitry 500 includes modifications to the logic circuitry 302 to allow a mixture of BIST engines 106 running in serial or parallel. As shown in FIG. 5, an OR gate 502 has been added between the AND gates 410(1) and 410(2), and an OR gate 504 has been added between the AND gates 410(2) and 410(3). Similar modifications may be made to the other sets of AND gates 412, 414, 416, 418, and 420. As with logic circuitry 302, the output of the AND gates in logic circuitry 500 is used to start the next BIST engine 106. However, this can be overridden by the register 506 and OR gates 502 and 504.

Register 506 provides a START_SELECT signal to an input of OR gate 502 and an input of OR gate 504. In some examples, the START_SELECT signal is a two-bit value. When START_SELECT has a value of 00, the register 506 provides a logical “0” to both OR gates 502 and 504, and the AND gates 410(1)-410(3) cause a serial ordering of the BIST engines 106 in the serial order: BIST engine 106(1)->BIST engine 106(2)->BIST engine 106(3) as described above with reference to FIG. 4. When START_SELECT has a value of 01, the register 506 provides a logical “0” to OR gate 502 and a logical “1” to OR gate 504, and the AND gates 410(1)-410(3) cause a partial serial and partial parallel ordering of the BIST engines 106 in the order: BIST engine 106(1)+BIST engine 106(3)->BIST engine 106(2). The logical “1” at OR gate 504 causes BIST engine 106(3) to start at the same time as BIST engine 106(1), and when these engines are done, BIST engine 106(2) starts.

When START_SELECT has a value of 10, the register 506 provides a logical “1” to OR gate 502 and a logical “0” to OR gate 504, and the AND gates 410(1)-410(3) cause a partial serial and partial parallel ordering of the BIST engines 106 in the order: BIST engine 106(1)+BIST engine 106(2)->BIST engine 106(3). The logical “1” at OR gate 502 causes BIST engine 106(2) to start at the same time as BIST engine 106(1), and when these engines are done, BIST engine 106(3) starts. When START_SELECT has a value of 11, the register 506 provides a logical “1” to OR gate 502 and a logical “1” to OR gate 504, and the AND gates 410(1)-410(3) cause a completely parallel ordering of the BIST engines 106: BIST engine 106(1)+BIST engine 106(2)+BIST engine 106(3). The logical “1” at OR gates 502 and 504 causes BIST engines 106(2) and 106(3) to start at the same time as BIST engine 106(1).

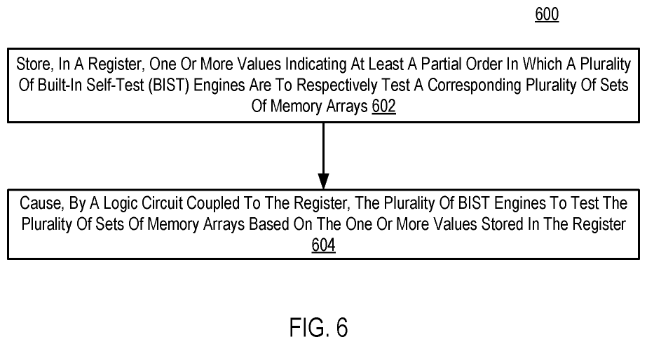

FIG. 6 sets forth a flowchart of an example method 600 for reconfigurable testing of an integrated circuit according to aspects of the present disclosure. In a particular embodiment, the method 600 is performed utilizing logic circuitry 104 (FIG. 1). The method 600 includes storing 602, in a register, one or more values indicating at least a partial order in which a plurality of built-in self-test (BIST) engines are to respectively test a corresponding plurality of sets of memory arrays. The method 600 further includes causing 604, by a logic circuit coupled to the register, the plurality of BIST engines to test the plurality of sets of memory arrays based on the one or more values stored in the register.

Some examples disclosed herein are directed to reconfigurable testing of an integrated circuit, which includes a register that stores a desired order of BIST engines that will test their connected array group. A multiplexer may choose which BIST engine in the sequence will first begin test of their array group based on a value in the register. The desired sequence may be decided from tests in hardware or simulation. The order of the sequence may be selected to balance the power across the period of test, which may be achieved by limiting the number of engines and array groups that are running at once. The sequential order of test may avoid the power spike caused by all BIST engines running at once at the start of test.

In some examples, the register stores the first BIST engine in sequence. The register may create a loop of connected BIST engines where a DONE output from each engine will signal the next BIST engine in the sequence to begin testing its connected array group. The starting engine in the sequence may be programmable to any one of the BIST engines.

In some examples, the BIST engine sequence is fully programmable from the starting engine to the next and so on, for all BIST engines available. This allows for full reconfiguration of the sequence based on empirical data after hardware arrives to achieve the best power and closest implementation to mimic the functional power.

In some examples, a full cross point switch selectively programs some (e.g., lower power) BIST engines to run in parallel and other (e.g., high power) BIST engines to run in serial fashion. These examples provide flexibility and allow options from testing all BIST engines in parallel (e.g., small, low power chip) to running every engine in a serial mode (e.g., high power chips).

Some examples provide the option to run all BIST engines or a partial subset of BIST engines in parallel mode, enabling stress test of the power distribution. This will force high power during testing, allowing for a search of outlier chips that are at higher risk of failing with aggressive workloads.

In some examples, the BIST engine sequence may be setup to boot up in random modes during the chip test so a different, unpredictable power signature is observed at different times, thereby enhancing security by obfuscating power usage.

Some examples are directed to sequencing memory array BIST. Some examples sequence the tests of the different memory blocks/groups with on chip BIST engines to optimize power during the memory test. Some examples create a more realistic power dissipation during BIST by running memory block/groups in a programmable sequence, as opposed to achieving low power by replacing scan chains or through changes in BIST architecture circuitry. Some examples provide flexibility and adaptability in scheduling the various test controllers and may accommodate non-ABIST power/workloads that may be present during many aspects/environments of self test. Some examples may be used with any of a variety of controller implementations/types and is not dependent on any one controller style, but provides flexibility in managing/scheduling the operations of the controllers.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for reconfigurable testing of an integrated circuit, comprising:
storing, in a register, one or more values indicating at least a partial order in which a plurality of built-in self-test (BIST) engines are to respectively test a corresponding plurality of sets of memory arrays; and
causing, by a logic circuit coupled to the register, the plurality of BIST engines to test the plurality of sets of memory arrays based on the one or more values stored in the register.

2. The method of claim 1, wherein the one or more values stored in the register are determined based on tests in hardware or simulation.

3. The method of claim 1, wherein the one or more values stored in the register indicate an ordering of the plurality of BIST engines that balances power across a total period of testing.

4. The method of claim 1, wherein the logic circuit selects a first one of the BIST engines to run before other ones of the BIST engines based on the one or more values stored in the register, and wherein the other ones of the BIST engines run in a predetermined sequence following the running of the first one of the BIST engines.

5. The method of claim 4, wherein the first one of the BIST engines sends a signal to a second one of the BIST engines upon completion of testing by the first one of the BIST engines to cause the second one of the BIST engines to begin testing.

6. The method of claim 1, wherein the one or more values stored in the register indicate a complete order in which the plurality of BIST engines are to sequentially test the plurality of sets of memory arrays.

7. The method of claim 6, wherein the logic circuit includes a multiplexer coupled to the register to selectively output one of a plurality of possible orders of the BIST engines based on the one or more values stored in the register.

8. The method of claim 1, wherein the method further comprises:
causing, by the logic circuit, a first subset of the BIST engines to run in parallel and a second subset of the BIST engines to run in a serial manner.

9. A system comprising:
a plurality of sets of memory arrays;
a plurality of built-in self-test (BIST) engines;
a register to store one or more values indicating at least a partial order in which the plurality of BIST engines are to respectively test the plurality of sets of memory arrays; and
a logic circuit coupled to the register to cause the plurality of BIST engines to test the plurality of sets of memory arrays based on the one or more values stored in the register.

10. The system of claim 9, wherein the one or more values stored in the register are determined based on tests in hardware or simulation.

11. The system of claim 9, wherein the one or more values stored in the register indicate an ordering of the plurality of BIST engines that balances power across a total period of testing.

12. The system of claim 9, wherein the logic circuit selects a first one of the BIST engines to run before other ones of the BIST engines based on the one or more values stored in the register, and wherein the other ones of the BIST engines run in a predetermined sequence following the running of the first one of the BIST engines.

13. The system of claim 12, wherein the first one of the BIST engines sends a signal to a second one of the BIST engines upon completion of testing by the first one of the BIST engines to cause the second one of the BIST engines to begin testing.

14. The system of claim 9, wherein the one or more values stored in the register indicate a complete order in which the plurality of BIST engines are to sequentially test the plurality of sets of memory arrays.

15. The system of claim 14, wherein the logic circuit includes a multiplexer coupled to the register to selectively output one of a plurality of possible orders of the BIST engines based on the one or more values stored in the register.

16. The system of claim 9, wherein the logic circuit causes a first subset of the BIST engines to run in parallel and a second subset of the BIST engines to run in a serial manner.

17. An apparatus for reconfigurable testing of an integrated circuit, comprising:
a plurality of built-in self-test (BIST) engines;
a register to store one or more values indicating at least a partial order in which the plurality of BIST engines are to respectively test a corresponding plurality of sets of memory arrays; and
a logic circuit coupled to the register to cause the plurality of BIST engines to test the plurality of sets of memory arrays based on the one or more values stored in the register.

18. The apparatus of claim 17, wherein the logic circuit selects a first one of the BIST engines to run before other ones of the BIST engines based on the one or more values stored in the register, and wherein the other ones of the BIST engines run in a predetermined sequence following the running of the first one of the BIST engines.

19. The apparatus of claim 17, wherein the one or more values stored in the register indicate a complete order in which the plurality of BIST engines are to sequentially test the plurality of sets of memory arrays.

20. The apparatus of claim 17, wherein the logic circuit causes a first subset of the BIST engines to run in parallel and a second subset of the BIST engines to run in a serial manner.
